(19) United States
(12) Patent Application Publication
(10) Pub. No.: US 2021/0405358 A1
(43) Pub. Date: Dec. 30, 2021

(54) COMPENSATION OF CREEP EFFECTS IN AN IMAGING DEVICE

(71) Applicant: Carl Zeiss SMT GmbH, Oberkochen (DE)

(72) Inventors: Eylem Bektas Knauf, Aalen (DE); Ulrich Schoenhoff, Ulm (DE); Marwène Nefzi, Ulm (DE); Ralf Zweering, Aalen (DE)

(21) Appl. No.: 17/354,116

(22) Filed: Jun. 22, 2021

(30) Foreign Application Priority Data
Jun. 29, 2020 (DE) 102020208012.7

(51) Int. Cl. G02B 27/00; G03F 7/20

(52) U.S. Cl. CPC G02B 27/0068; G03F 7/70825; G03F 7/70483; G03F 7/709

(57) ABSTRACT

An arrangement of a microlithographic optical imaging device includes first and second supporting structures. The first supporting structure supports an optical element of the imaging device. The first supporting structure supports the second supporting structure via supporting spring devices of a vibration decoupling device. The supporting spring devices act kinematically parallel to one another between the first and second supporting structures. Each supporting spring device defines a supporting force direction and a supporting length along the supporting force direction. The second supporting structure supports a measuring device which is configured to measure the position and/or orientation of the at least one optical element in relation to a reference in at least one degree of freedom. A creep compensation device compensates a creep-induced change in a static relative situation between the first and second supporting structures in at least one correction degree of freedom.

### CROSS-REFERENCE TO RELATED APPLICATIONS

This application claims priority under 35 U.S.C. § 119 to German patent application No. 10 2020 208 012.7, filed Jun. 29, 2020, the entire contents of which are incorporated by reference herein.

### FIELD

The present disclosure relates to a microlithographic optical arrangement suitable for utilizing UV used light, such as light in the extreme ultraviolet (EUV) range. Furthermore, the disclosure relates to an optical imaging device including such an arrangement. The disclosure can be used in conjunction with any desired optical imaging methods, such as in the production or the inspection of microelectronic circuits and the optical components used for that purpose (for example optical masks).

### BACKGROUND

The optical devices used in conjunction with the production of microelectronic circuits typically include a plurality of optical element units including one or more optical elements, such as lens elements, mirrors or optical gratings, which are arranged in the imaging light path. The optical elements typically cooperate in an imaging process in order to transfer an image of an object (for example a pattern formed on a mask) to a substrate (for example a so-called wafer). The optical elements are typically combined in one or more functional groups held, if appropriate, in separate imaging units. In the case of principally refractive systems that operate with a wavelength in the so-called vacuum ultraviolet range (VUV, for example at a wavelength of 193 nm), such imaging units are often formed from a stack of optical modules holding one or more optical elements. The optical modules typically include a supporting structure having a substantially ring-shaped outer supporting unit, which supports one or more optical element holders, the latter in turn holding the optical element.

The ever-advancing miniaturization of semiconductor components generally results in a constant demand for increased resolution of the optical systems used for their production. This demand for increased resolution can cause a demand for an increased numerical aperture (NA) and an increased imaging accuracy of the optical systems.

One approach for obtaining an increased optical resolution involves reducing the wavelength of the light used in the imaging process. The trend in recent years has increasingly fostered the development of systems in which light in the so-called extreme ultraviolet (EUV) range is used, typically at wavelengths of 5 nm to 20 nm, in most cases at a wavelength of approximately 13 nm. In this EUV range it is generally no longer possible to use conventional refractive optical systems. This is owing to the fact that in this EUV range the materials used for refractive optical systems generally have an absorbance that is too high to achieve acceptable imaging results with the available light power. Consequently, in this EUV range it is generally desirable to use reflective optical systems for the imaging.

This transition to purely reflective optical systems having a high numerical aperture (e.g. NA>0.4) in the EUV range can present challenges with regard to the design of the imaging device.

The factors mentioned above can result in very stringent desired properties with regard to the position and/or orientation of the optical elements participating in the imaging relative to one another and also with regard to the deformation of the individual optical elements in order to achieve a desired imaging accuracy. Moreover, it is generally desirable to maintain this high imaging accuracy over operation in its entirety, ultimately over the lifetime of the system.

As a consequence, it is desirable for the components of the optical imaging device (i.e., for example, the optical elements of the illumination device, the mask, the optical elements of the projection device and the substrate) which cooperate during the imaging to be supported in a well-defined manner in order to maintain a predetermined well-defined spatial relationship between these components and to obtain a minimal undesired deformation of these components in order ultimately to achieve the highest possible imaging quality.

A challenge in this case often relates to undertaking the most precise possible measurement of the relative situation (i.e., the position and/or orientation) of the optical components (e.g., the optical elements) involved in the imaging and actively setting the relative situation of at least some of these optical elements by way of an appropriately controlled relative situation control device with the precision (typically in the region of 1 nm or less) and control bandwidth (typically up to 200 Hz) used for the imaging process. In this case, a factor for the precision of the measurement is the stable and precise support of the measuring device used for the measurement. Where possible, it is desirable for this support to ensure that the components of the measuring device have a well-defined relative situation (i.e., position and/or orientation) in relation to a defined reference to which the measurement result of the measuring device is related.

An option frequently used in this context is that of supporting the measuring device on a separate supporting structure, which is often also referred to as “sensor frame” or “metrology frame”. In this case, such a sensor frame is typically supported on a further (single-part or multi-part) load-bearing structure (often also referred to as a “force frame”) which, in addition to the sensor frame, also supports at least some of the optical components (e.g., at least some of the optical elements) of the imaging device by way of the relative situation control device. This can ensure that the sensor frame can be kept largely clear from the support loads for the optical components.

To keep the sensor frame relatively free from internal disturbances of the imaging device (e.g., vibrations induced by moving components) and external disturbances (e.g., unwanted shocks) in this case, the sensor frame is frequently supported on the load-bearing structure in vibration-isolated or vibration-decoupled fashion by way of a vibration decoupling device. Typically, this is implemented by way of a plurality of supporting spring devices of the vibration decoupling device.

While this approach can achieve good dynamic vibration isolation of the sensor frame (on short time scales), it was found, however, that, over long time scales, so-called creep effects or settling effects can arise in the area of the vibration decoupling device, such as in the area of the supporting spring devices. As a result of this, in the long term, relative to the load-bearing structure, there can be a change in the relative situation of the sensor frame and hence a change in the relative situation of the reference used for controlling the relative situation control device. Such a change in the static relative situation of the reference is typically compensated for by the relative situation control device during operation; however, it is desired that the latter provides sufficient travel to this end, and consequently a sufficient motion reserve, and accordingly has a correspondingly complicated or expensive design.

### SUMMARY

The disclosure seeks to provide a microlithographic optical arrangement and a corresponding optical imaging device including such an arrangement, and a corresponding method, which reduce, and possibly avoid, limitations of known technology, and, for example, facilitate optical imaging with the highest possible imaging quality in the simplest and most cost-effective manner.

The disclosure involves the technical teaching that optical imaging with a high imaging quality can be easily and cost effectively obtained if a controllable active adjustment device acts kinematically parallel to the supporting spring devices between the load-bearing first supporting structure and the measuring device-bearing second supporting structure, wherein the adjustment force of the adjustment device isg able to be altered in order to at least partly compensate for a change in the static relative situation between the first supporting structure and the second supporting structure in at least one degree of freedom.

Starting from an initial state which the imaging device or its components, respectively, have following an initial adjustment of the imaging device (typically immediately following the first-time start-up of the imaging device), the adjustment device may be continuously active immediately and/or at least over relatively long periods of time. For example, any threshold (of the deviation from the initial state) can be specified for triggering an actuation of the adjustment device, such that the adjustment device immediately already at least partly compensates for correspondingly small deviations. Consequently, it is possible for the adjustment device to be active immediately upon first-time operation and to exert the adjustment force if the creep or settling effects are captured or have had a noticeable effect on the support of the second supporting structure in order to at least partly compensate for these effects. However, the adjustment device may also initially exert no adjustment force. Thus, if desired, the adjustment device may only become active at a later time, for example after creep or settling effects in the support of the second supporting structure have had a noticeable effect, in order to at least partly compensate for these effects.

Within the meaning of the present disclosure, the term “change in static relative situation” should be understood to mean that this is the change in the relative situation or a drift between the first supporting structure and the second supporting structure, which is present in the purely static state, i.e., without dynamic excitation of the structures. As will still be explained in more detail below, such a change in the static relative situation or drift can be detected by way of suitable methods which filter out short-term or dynamic influences. By way of example, there can be simple averaging of the relative situation information over suitably long periods of time.

In the case of conventional designs, depending on the extent of the change in static relative situation, there may be a comparatively pronounced static (or non-dynamic) deflection of the relative situation control device and hence of the optical elements from their original initial relative situation, by which this change in the static relative situation is compensated for, hence the optical elements follow this change in the static relative situation. This can go so far that the relative situation control device is no longer able to supply the travel used for the dynamic relative situation control of the optical elements during operation since it reaches its limits in this respect.

In conventional designs, this conflict is solved by virtue of the relative situation control device being designed with correspondingly large room for maneuver, which allows it to react accordingly over the service life of the imaging device. However, this is linked to comparatively high costs since a displacement motion with correspondingly high dynamics, for example, can only be realized with comparatively great outlay. The part of the dynamic room for maneuver of the relative situation control device using which the optical elements follow the change in static relative situation is thus ultimately wasted from a costs point of view.

By contrast, using the present correction or compensation, it can be possible to return the second supporting structure, and hence the reference, back to its initial state (or to the vicinity thereof), as exhibited after an initial adjustment of the imaging device (typically immediately during first-time start-up of the imaging device), immediately or after a certain time of operation, possibly even a relatively long time of operation, over which the creep or settling effects have had a noticeable effect on the support of the second supporting structure. As a consequence, the relative situation control device, which follows the reference, and the optical elements carried by the relative situation control device, respectively, are then returned back to their initial state. A drift of the relative situation control device is consequently at least substantially removed.

As a result, it is possible, in a simple manner, to keep the maximum used or possible travel of the relative situation control device relatively small or restricted to the bare minimum. For example, there is no need to keep a large motion reserve for the compensation of long-term creep or settling effects. This motion reserve can be kept significantly smaller.

According to one aspect, the disclosure relates to an arrangement of a microlithographic optical imaging device, for example for using light in the extreme UV (EUV) range, including a first supporting structure and a second supporting structure, wherein the first supporting structure is configured to support at least one optical element of the imaging device. The first supporting structure supports the second supporting structure by way of a plurality of supporting spring devices of a vibration decoupling device, wherein the supporting spring devices act kinematically parallel to one another between the first supporting structure and the second supporting structure. Each of the supporting spring devices defines a supporting force direction, along which it exerts a supporting force between the first supporting structure and the second supporting structure, and defines a supporting length along the supporting force direction. The second supporting structure supports a measuring device which is configured to measure the position and/or orientation of the at least one optical element in relation to a reference, for example a reference of the second supporting structure, in at least one degree of freedom up to all six degrees of freedom in space. Provision is made of a creep compensation device for compensating a change in the static relative situation between the first supporting structure and the second supporting structure in at least one correction degree of freedom, wherein the change in the static relative situation, for example, is caused by a creep process at the supporting spring devices, for example, a change in length of at least one of the supporting spring devices along their supporting force direction, which arises from a creep process of the supporting spring device. The creep compensation device includes a controllable active adjustment device which has at least one active actuator unit and which acts kinematically parallel to the supporting spring devices between the first supporting structure and the second supporting structure. The adjustment device is configured to exert an adjustment force on the second supporting structure and to alter the adjustment force for at least partial compensation of the change in the static relative situation.

In general, the adjustment device can be designed in any suitable way for generating the adjustment force. Optionally, its stiffness is naturally matched to the stiffness of the supporting spring devices in order to obtain the desired decoupling effect of the vibration decoupling device in the desired decoupling degrees of freedom. Optionally, the adjustment device is designed in such a way that it supplies the smallest possible contribution to the stiffness of the support of the second supporting structure in these decoupling degrees of freedom, in which the vibration decoupling device should provide decoupling. Optionally, the adjustment device supplies substantially no contribution to the stiffness of the support of the second supporting structure in these decoupling degrees of freedom. However, the active adjustment device may also be designed in such a way that it has a negative stiffness (hence its contribution to the support of the second supporting structure decreases with increasing deflection), as will yet be explained in more detail below.

In general, any suitable actuator units can be used to produce the adjustment force. In some embodiments, the adjustment device includes at least one active actuator unit with a reluctance actuator. These reluctance actuators (which are based on the effect of the action of force for minimizing the magnetic resistance—the reluctance—in a magnetic circuit) can for example be desirable over Lorentz actuators, for example, in that they can produce a comparatively large adjustment force while using comparatively small installation space and developing comparatively little heat. Moreover, some reluctance actuators have a stiffness that, over a certain actuation range, is at least substantially equal to zero upon deflection from their rest situation (i.e., the situation with minimized reluctance). However, it is likewise possible to use reluctance actuators which have a negative stiffness in the manner described above. In addition or as an alternative thereto, the adjustment device can also include at least one active actuator unit with a Lorentz actuator. These, too, can be desirable in that they have a stiffness which is at least substantially equal to zero over a certain actuation range.

In general, the interplay between the supporting spring devices and the adjustment device can be configured in any suitable manner in order to obtain the desired vibration-decoupled support of the second supporting structure. Thus, the adjustment device can be configured in such a way that the adjustment force at least partly relieves the supporting spring devices and the adjustment force is increased for at least partial compensation of the change in the static relative situation. However, the adjustment device can likewise also be configured in such a way that the adjustment force pre-stresses the supporting spring devices and the adjustment force is reduced for at least partial compensation of the change in the static relative situation. In this case, the respective adjustment device can also be designed in such a way that it includes actuator units acting in opposite ways (in the style of agonists and antagonists), which then sum up to generate a corresponding total adjustment force.

In certain embodiments, the adjustment device for relieving the supporting spring devices is configured in such a way that the adjustment force compensates at least a fraction of the total weight of the second supporting structure and the components carried by the second supporting structure. In this case, it can be sufficient to configure the adjustment device in such a way that a correction of the creep or settling effects at the supporting spring devices can be achieved. It can be desirable for this fraction is at least 0.1% to 30% (e.g., at least 0.5% to 6%, at least 1% to 3%) of the total weight. However, it may also be desirable in certain embodiments if at least a majority of the total weight is absorbed by the adjustment force, the supporting spring devices hence being significantly relieved from the static loads and there also being reduced creep or settling effects on account of this relief.

The at least one active actuator unit of the adjustment device, in general, can be functionally assigned, for example spatially assigned, to the supporting spring devices in any suitable manner. Naturally, this is optionally implemented in coordination with an expected creep or settling behavior of the supporting spring devices. It can be desirable for at least one active actuator unit to be functionally assigned, for example spatially assigned, to at least one of the supporting spring devices. A simple coordination with simple needs-based compensation of creep or settling effects is possible if at least one active actuator unit, for example exactly one active actuator unit, is functionally assigned to each of a plurality of the supporting spring devices, for example to each of the supporting spring devices.

In certain embodiments, at least one active actuator unit includes at least one reluctance actuator with a first magnetic circuit component and a second magnetic circuit component, which are assigned to one another for contactless interaction. In this case, the first magnetic circuit component can be mechanically connected to the first supporting structure and the second magnetic circuit component can be mechanically connected to the second supporting structure. In addition or as an alternative thereto, one of the magnetic circuit components, for example the first magnetic circuit component, can include a coil unit which is connectable to a voltage source for the purposes of generating a magnetic field in the reluctance actuator. This can enable the magnetic flux in the magnetic circuit, and hence the adjustment force, to be adjusted in a relatively simple manner.

In general, the reluctance actuator can be designed in any desired way. Thus, for example, it can be designed in the style of a lifting magnet, in which the contribution to the adjustment force results from the fact that a magnetic circuit of the reluctance actuator attempts to reduce at least one air gap of the magnetic circuit. Such a lifting magnet typically has a force profile in which the force decreases with an increase in the air gap. This “negative” stiffness can be used in certain embodiments in coordination with the supporting spring devices, as has already been described.

Embodiments with a relatively simple design can arise if a first magnetic core unit of the first magnetic circuit component and a second magnetic core unit of the second magnetic circuit component, under the formation of two air gaps, form a magnetic core of a magnetic circuit of the reluctance actuator. In this case, the reluctance actuator then has a reference state, in which the magnetic circuit has a minimized magnetic resistance (i.e., a minimized reluctance). Furthermore, the reluctance actuator has an actuating state, in which the reluctance actuator supplies at least a contribution to the adjustment force. In this case, the reluctance actuator is configured in such a way that a magnetic field is generated in the first magnetic core unit and in the second magnetic core unit, the magnetic field lines of the magnetic field, in the reference state, respectively passing through the air gaps in a magnetic field line direction. Furthermore, the reluctance actuator is configured and arranged in such a way that the first magnetic core unit and the second magnetic core unit, in the actuating state, are deflected transversely to the magnetic field line direction with respect to one another as compared to the reference state.

In certain embodiments, the at least one active actuator unit may be configured in such a way that the contribution of the actuator unit to the adjustment force proportionally decreases, at least in sections, with increasing change in the static relative situation. In addition or as an alternative thereto, the at least one active actuator unit can be configured in such a way that the contribution of the actuator unit to the adjustment force over-proportionately decreases, at least in sections, with increasing change in the static relative situation. Expressed differently, the actuator unit has a negative stiffness, as a result of which the stiffness of the supporting spring devices can be at least partly absorbed or compensated for. As a result of this, it is possible, for example, to use supporting spring devices with a higher stiffness, which are therefore subject to creep and settling effects to a lesser extent. The increased stiffness of the supporting spring devices can then be compensated for by the negative stiffness of the actuator unit(s), such that, in total, at least a nevertheless comparatively low stiffness is obtained in the decoupling degrees of freedom.

In addition or as an alternative thereto, the at least one active actuator unit can be configured in such a way that the contribution of the actuator unit to the adjustment force is substantially constant, at least in sections, with increasing change in the static relative situation. With this, it is then possible to realize the stiffness near or equal to zero, as already described above, in this area of the deflection.

In general, the at least one active actuator unit can be designed in such a way that it itself already provides the desired decoupling in the decoupling degrees of freedom involved (for the support of the second supporting structure). In some embodiments, during operation the at least one active actuator unit exerts its contribution to the adjustment force on the second supporting structure in an adjustment force direction, wherein the at least one active actuator unit is mechanically connected to one of the supporting structures, for example to the second supporting structure, by way of a decoupling device. Here, the decoupling device is configured to generate at least partial mechanical decoupling between the actuator unit and the supporting structure in at least one decoupling degree of freedom that differs from the adjustment force direction. Here, the at least one decoupling degree of freedom can be a translational degree of freedom which extends transversely to the adjustment force direction. In addition or as an alternative thereto, the at least one decoupling degree of freedom can be a rotational degree of freedom about an axis which extends transversely to the adjustment force direction. A vibration decoupling can be obtained in a simple manner in all these cases.

In certain embodiments that can be relatively easy to realize, during operation, the at least one active actuator unit exerts its contribution to the adjustment force on one of the supporting structures in an adjustment force direction, wherein the at least one active actuator unit is mechanically connected to the supporting structure by way of a decoupling device, which extends in the adjustment force direction. In this case, the decoupling device can include a flexible decoupling element that is elongated in the adjustment force direction in order to achieve the decoupling in a simple manner. In addition or as an alternative thereto, the decoupling device can include a leaf spring element that is elongated in the adjustment force direction in order to achieve the decoupling in a simple manner. In addition or as an alternative thereto, the decoupling device can include a narrow, for example flexible, rod spring element that is elongated in the adjustment force direction in order to achieve the decoupling in a simple manner.

In certain embodiments, a control device is provided, which is configured to control, in a creep compensation mode, the adjustment device for changing the adjustment force on the basis of the change in length of the at least one supporting spring device along its supporting force direction. In this case, the change in length of the at least one supporting spring device can be established in any suitable way. Thus, any one or more suitable detection variables can be detected by way of appropriate detection devices, which allow conclusions to be drawn about the change in length. Likewise, the control device can additionally or alternatively use a creep model of the supporting spring device, which describes the creep behavior of the supporting spring device, to determine the change in length of the at least one supporting spring device along its supporting force direction.

In certain embodiments, provision is made of a detection device and a control device, wherein the detection device is configured to detect at least one relative situation detection value which is representative for the relative situation between the first supporting structure and the second supporting structure in at least one correction degree of freedom and output the relative situation detection value to the control device. In a creep compensation mode, the control device is configured to control the adjustment device to change the adjustment force, on the basis of the relative situation detection value, for example on the basis of a change in the relative situation detection value over time.

In general, changing the adjustment force in a creep compensation mode can be implemented at any suitable time or triggered by any temporal events (e.g., specifiable intervals) and/or non-temporal events (e.g., detected shock loads, reaching a certain number of imaging procedures, starting up or shutting down the imaging device, etc.).

In certain embodiments, the control device is configured to activate the creep compensation mode if a relative situation change represented by relative situation change information or a relative situation detection value exceeds a specifiable limit value. As a result of this, it is naturally possible to react relatively efficiently and in needs-based fashion to the creep or settling effects. Here, a discrete (intermittent) activation of the creep compensation mode may be realized, depending on the choice of the limit value. Likewise, continuous control can ultimately also be realized, the creep compensation mode hence being permanently active.

Additionally or alternatively, the control device can be configured to activate the creep compensation mode on the basis of specifiable events, for example at specifiable time intervals, wherein the creep compensation mode is activated, for example, 1 μs to 10 years (e.g., 1 ms to 3 years, 10 minutes to 1 year) following the first operation of the imaging device and/or a preceding activation of the creep compensation mode.

In general, the control device can be designed in any suitable manner in order to realize a control of the adjustment device that is adapted to the respective optical imaging process. It is possible, for example, to provide any suitable control bandwidths for controlling the adjustment device. In some embodiments, the control device has a control bandwidth of 0.5 μHz to 500 Hz (e.g., 0.01 Hz to 100 Hz, 0.1 Hz to 10 Hz).

The degree of freedom or the degrees of freedom in which, as a result of creep or settling effects, there is a change in the static relative situation relevant to the imaging process or the imaging errors thereof can be any degrees of freedom, up to all six degrees of freedom in space. Here, any suitable limit values can be specified, which, when exceeded, involve or trigger the change in the adjustment force.

In certain embodiments, the at least one degree of freedom of the change in the static relative situation is a rotational degree of freedom, for example a rotational degree of freedom about a tilt axis extending transversely to the direction of gravity. The specifiable limit value then can be representative for a deviation of the relative situation between the first supporting structure and the second supporting structure from a specifiable relative target situation by 0.1 μrad to 1000 μrad (e.g., 1 μrad to 200 μrad, 10 μrad to 100 μrad). In addition or as an alternative thereto, the at least one degree of freedom of the change in the static relative situation can be a translational degree of freedom, for example a translational degree of freedom along the direction of gravity. The specifiable limit value then can be representative for a deviation of the relative situation between the first supporting structure and the second supporting structure from a specifiable relative target situation by 0.1 μm to 1000 μm (e.g., 1 μm to 200 μm, 10 μm to 100 μm).

The present disclosure also relates to an optical imaging device, for example for microlithography, including an illumination device including a first optical element group, an object device for receiving an object, a projection device including a second optical element group and an image device, wherein the illumination device is configured to illuminate the object and the projection device is configured to project an image of the object onto the image device. The illumination device and/or the projection device includes at least one arrangement according to the disclosure. This makes it possible to realize the embodiments and features described above to the same extent, and so reference is made to the explanations given above in this respect.

The present disclosure furthermore relates to a method for a microlithographic optical imaging device, for example for using light in the extreme UV (EUV) range, wherein a first supporting structure supports a second supporting structure by way of a plurality of supporting spring devices of a vibration decoupling device and is configured to support at least one optical element of the imaging device, wherein the supporting spring devices act kinematically parallel to one another between the first supporting structure and the second supporting structure. Each of the supporting spring devices defines a supporting force direction, along which it exerts a supporting force between the first supporting structure and the second supporting structure, and defines a supporting length along the supporting force direction. The second supporting structure supports a measuring device which is configured to measure the position and/or orientation of the at least one optical element in relation to a reference, for example a reference of the second supporting structure, in at least one degree of freedom up to all six degrees of freedom in space. A change in the static relative situation between the first supporting structure and the second supporting structure is at least partly compensated for in at least one degree of freedom in a compensation step, wherein the change in the static relative situation, for example, is caused by a creep process at the supporting spring devices, for example, a change in length of at least one of the supporting spring devices along their supporting force direction, which arises from a creep process of the supporting spring device. In this case, a adjustment force is exerted on the second supporting structure in a manner kinematically parallel to the supporting spring devices between the first supporting structure and the second supporting structure, wherein the adjustment force is altered for at least partial compensation of the change in the static relative situation. This likewise makes it possible to realize the embodiments and features described above to the same extent, and so reference is made to the explanations given above in this respect.

To generate the adjustment force, use is optionally made of at least one active actuator unit with a reluctance actuator and/or at least one active actuator unit with a Lorentz actuator. Furthermore, the adjustment force can at least partly relieve the supporting spring devices and the adjustment force can be increased for at least partial compensation of the change in the static relative situation. Alternatively, the adjustment force can pre-stress the supporting spring devices and the adjustment force can be reduced for at least partial compensation of the change in the static relative situation.

Further aspects and exemplary embodiments of the disclosure are evident from the dependent claims and the following description of exemplary embodiments, which relates to the accompanying figures. All combinations of the disclosed features, irrespective of whether or not they are the subject of a claim, lie within the scope of protection of the disclosure.

### BRIEF DESCRIPTION OF THE DRAWINGS

FIG. 1 is a schematic illustration of an embodiment of an optical imaging device according to the disclosure, which includes an embodiment of an optical arrangement according to the disclosure.

FIG. 2 is a schematic view of part of the imaging device from FIG. 1 in a first state.

FIG. 3 is a schematic view of the part of the imaging device from FIG. 2 in a second state.

FIG. 4 is a schematic view of the part of an embodiment of the imaging device from FIG. 2.

FIG. 5 is a schematic view of the part of an embodiment of the imaging device from FIG. 2.

FIG. 6 is a schematic view of the part of an embodiment of the imaging device from FIG. 2.

FIG. 7 is a schematic view of the part of an embodiment of the imaging device from FIG. 2.

FIG. 8 is a flowchart of an exemplary embodiment of a method according to the disclosure, which can be carried out using the imaging device from FIG. 1.

### DETAILED DESCRIPTION OF EXEMPLARY EMBODIMENTS

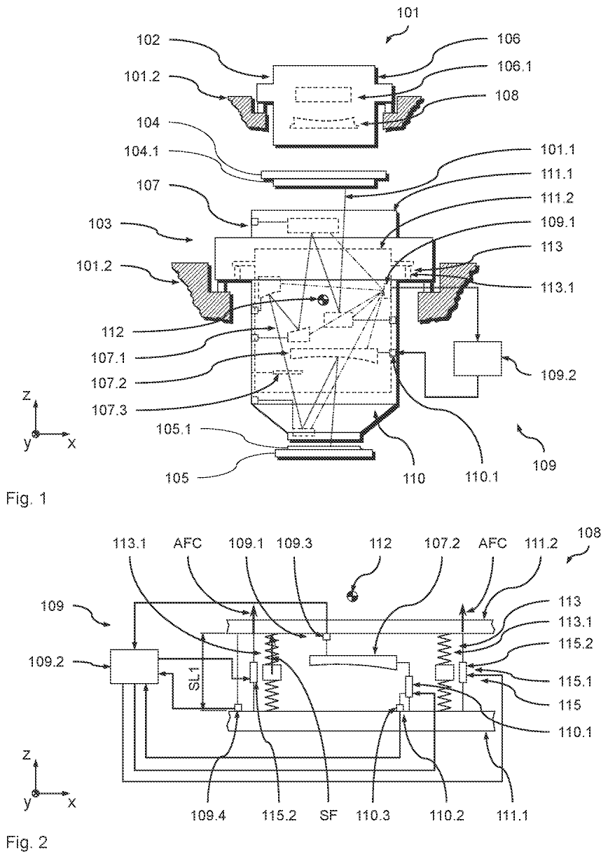

Exemplary embodiments of an optical imaging device according to the disclosure in the form of a microlithographic projection exposure apparatus 101, which include exemplary embodiments of an optical arrangement according to the disclosure, are described below with reference to FIGS. 1 to 8. To simplify the following explanations, an x, y, z coordinate system is indicated in the drawings, the z direction running counter to the direction of gravitational force. It goes without saying that it is possible in further configurations to choose any desired other orientations of an x, y, z coordinate system.

FIG. 1 is a schematic, not-to-scale representation of the projection exposure apparatus 101, which is used in a microlithographic process for producing semiconductor components. The projection exposure apparatus 101 includes an illumination device 102 and a projection device 103. The projection device 103 is designed to transfer, in an exposure process, an image of a structure of a mask 104.1, which is disposed in a mask unit 104, onto a substrate 105.1, which is disposed in a substrate unit 105. For this purpose, the illumination device 102 illuminates the mask 104.1. The optical projection device 103 receives the light from the mask 104.1 and projects the image of the mask structure of the mask 104.1 onto the substrate 105.1, such as for example a wafer or the like.

The illumination device 102 includes an optical unit 106 including an optical element group 106.1. The projection device 103 includes a further optical unit 107 including an optical element group 107.1. The optical element groups 106.1, 107.1 are disposed along a folded central ray path 101.1 of the projection exposure apparatus 101. Each optical element group 106.1, 107.1 can include any plurality of optical elements.

In the present exemplary embodiment, the projection exposure apparatus 101 operates with used light in the EUV range (extreme ultraviolet radiation), with wavelengths of between 5 nm and 20 nm, for example with a wavelength of 13 nm. The optical elements of the element groups 106.1, 107.1 of the illumination device 102 and the projection device 103 are therefore exclusively reflective optical elements. The optical element groups 106.1, 107.1 may include one or more optical arrangements according to the disclosure, as is described below with reference to the optical arrangement 108. The optical units 106 and 107 are each supported by way of a base structure 101.2.

In further configurations of the disclosure, it is also possible (for example depending on the wavelength of the illumination light), of course, to use any type of optical element (refractive, reflective, diffractive) alone or in any desired combination for the optical modules.

The arrangement according to the disclosure is described in exemplary fashion below with reference to the arrangement 108, which is part of the projection device 103. The imaging device 101, inter alia, is subject to very strict desired properties with respect to the position and/or orientation of the optical elements of the optical element group 107.1 of the projection device 103 relative to one another in order to attain a desired imaging accuracy. Moreover, it is desirable to maintain this high imaging accuracy over its entire operation, ultimately over the lifetime of the system.

As a consequence, the optical elements of the optical element group 107.1 must be supported in a well-defined fashion in order to observe a specified well-defined spatial relationship between the optical elements of the element group 107.1 and the remaining optical components in order, thus, to ultimately attain the highest possible imaging quality.

To this end, in the present example the relative situation (i.e., the position and/or orientation) of the optical elements of the element group 107.1 is measured with a measuring device 109.1 (illustrated only in much simplified fashion in FIG. 1) of a control device 109. The measuring device 109.1 feeds its measurement signals LMS to a control unit 109.2 of the control device 109. On the basis of the measurement signals LMS of the measuring device 109.1, the control unit 109.2 then controls a relative situation control device 110, which is supported on a load-bearing first structure 111.1. Then, by way of the relative situation control device 110, the relative situation of each optical element of the element group 107.1 is actively set with respect to a central reference 112 with the precision (typically in the region of 1 nm and less) and the control bandwidth (typically up to 200 Hz) used for the imaging process.

In the present example, the measuring device 109.1 outputs to the relative situation control device 110 measurement information MI which is representative for the respective position and/or orientation of the respective optical element of the element group 107.1 in relation to the reference 112 in at least one degree of freedom in space. In the state of the first-time start-up of the imaging device 101 (in which the imaging device 101 is in a first operating state OM1), the control unit 109.2 consequently accordingly controls the relative situation control device 110 on the basis of the measurement information MI in order to generate a first target state Si of the position and/or orientation of the optical elements of the element group 107.1 in relation to the reference 112, as illustrated in FIG. 2 for an optical element 107.2 of the element group 107.1.

A factor for the attainable imaging quality of the imaging device 101 is the precision of the measurement of the measuring device 109.1, which in turn depends on a support of the measuring device 109.1 that is as stable and precise as possible. Where possible, this support should ensure that the components of the measuring device 109.1 have a well-defined relative situation (i.e., position and/or orientation) in relation to the central reference 112 to which the measurement result of the measuring device 109.1 is related.

To this end, the measuring units 109.3 of the measuring device 109.1 are supported on a separate second supporting structure 111.2, which is frequently also referred to as a sensor frame. The sensor frame 111.2 in turn is supported on the (single-part or multi-part) load-bearing first supporting structure 111.1. This can ensure that the sensor frame 111.2 can be kept largely clear from the support loads for the optical elements of the element group 107.1.

To keep the sensor frame 111.2 as free as possible from internal disturbances of the imaging device 101 (e.g., vibrations induced by moving components) and external disturbances (e.g., unwanted shocks), the sensor frame 111.2 is supported on the load-bearing structure 111.1 in vibration-isolated or vibration-decoupled fashion by way of a vibration decoupling device 113. This is implemented by way of a plurality of supporting spring devices 113.1 of the vibration decoupling device 113, wherein the supporting spring devices 113.1 act kinematically parallel to one another between the load-bearing first supporting structure 111.1 and the sensor frame 111.2. Each of the supporting spring devices 113.1 defines a supporting force direction SFR, along which it exerts a supporting force SF between the first supporting structure 111.1 and the second supporting structure 111.2, and defines a supporting length SL1 along the supporting force direction SFR.

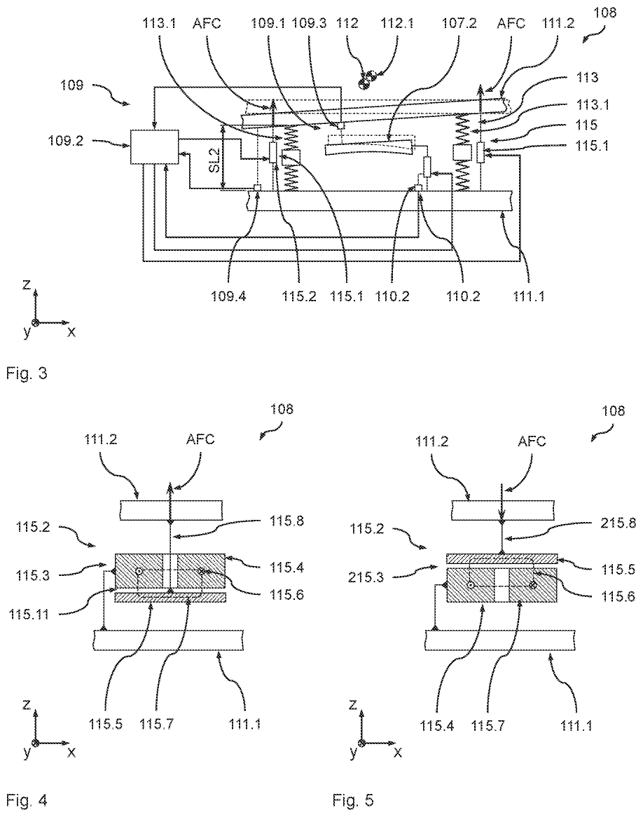

While this can achieve good dynamic vibration isolation or vibration decoupling of the sensor frame 111.2 from the load-bearing first supporting structure 111.1 (on short time scales), it was found, however, that so-called creep effects or settling effects can arise in the area of the vibration decoupling device 113, such as in the region of the supporting spring devices 113.1, over long time scales. As a result of this, the supporting length of the supporting spring devices 113.1 changes in the long-term (as indicated in FIGS. 3 and 4 by the length SL2) and hence there is a change both in the relative situation of the sensor frame 111.2 and in the relative situation of the reference 112 used for controlling the relative situation control device 110 with respect to the load-bearing structure 111.1 (in relation to the initial relative situation indicated in FIG. 3 by the contour 112.1). This is illustrated (in very much exaggerated fashion) in FIG. 3. In general, such a change in the static relative situation of the reference 112 can be compensated for by the relative situation control device 110 during normal operation of the imaging device 101 by virtue of the optical elements of the element group 107.1 of the reference 112 being adjusted (as illustrated in FIG. 3). However, such a compensation of the change in the static relative situation of the reference 112 by the relative situation control device 110 over the service life of the imaging device 101 would however involve sufficient travel, hence a sufficient motion reserve of the relative situation control device 110, as a result of which the latter must have a correspondingly complicated or expensive design.

To avoid this, in the present example, a creep compensation device 115 is provided for compensating such a change in the static relative situation between the first supporting structure 111.1 and the second supporting structure 111.2 in at least one correction degree of freedom. The creep compensation device 115 includes a controllable active adjustment device 115.1 which acts kinematically parallel to the supporting spring devices between the first supporting structure and the second supporting structure and which has a number of active actuator units 115.2, which can be controlled by the control unit 109.2. In the present example, the adjustment device 115.1 exerts a first adjustment force AFT1 on the sensor frame/frames 111.2 in the first mode of operation OM1, the first adjustment force being the result of the individual adjustment force contributions SFC of the active actuator units 115.2. As will yet be explained in more detail below, the adjustment force AFT is altered for compensating the change in the static relative situation on the part of the control unit.

To this end, the control device 109 in the present example detects relative situation change information RSCI which is representative for a change in the static relative situation between the load-bearing first supporting structure 110.1 and the second supporting structure 110.2 in at least one degree of freedom. The control device 109 includes a creep compensation mode CCM, in which the active adjustment device 115.1 is controlled by the control unit 109.2 in order to change the adjustment force contributions SFC of the active actuator units 115.2, and hence the adjustment force AFT, into a second adjustment force AFT2 on the basis of the relative situation change information RSCI. In this case, the second adjustment force AFT2 is chosen in such a way that the sensor frame 111.2 is returned back to the initial state illustrated in FIG. 2. Then, in a second mode of operation OM2 following the creep compensation mode CCM, the active adjustment device 115.1 exerts the second adjustment force AFT2 on the sensor frame/frames 111.2

It is understood that the control of the adjustment device 115.1 can be realized both as a closed loop control circuit (in which the relative situation change information RSCI is actually detected by way of appropriate detection signals) and as an open loop controlled system (in which the relative situation change information RSCI is determined by way of an appropriate model, for example), as this will be explained in more detail below.

Using this correction or compensation, it is possible, for example, in a simple manner to return the sensor frame 111.2, the reference 112 and hence the relative situation control device 110 (and the optical elements of the element group 107.1, for example the optical element 107.2, carried thereby) after a certain relatively long period of operation (over which the creep or settling effects have had a noticeable effect on the support of the second supporting structure 110.2) back to their initial state (or to the vicinity thereof), which they had following an initial adjustment of the imaging device (typically immediately during the first-time start-up of the imaging device 101), consequently in the first operating state OM1.

As a result, it is possible, for example in a simple manner, to keep the used maximum possible travel of the relative situation control device 110 relatively small or restricted to the bare minimum. For example, there is no need to keep a large motion reserve for the compensation of long-term creep or settling effects by the relative situation control device 110. This motion reserve can be kept significantly smaller and, for example, be restricted to a value to be expected for the duration of the first mode of operation OM1.

It is understood that the adjustment force AFT can be altered any desired number of times and that it is consequently possible to switch into the creep compensation mode CCM as often as desired. By this approach, it is possible to obtain a correspondingly desirable operational behavior over the entire service life of the imaging device 101.

In general, the change in the static relative situation or the associated relative situation change information RSCI can be determined in any suitable manner. The relative situation control device 110 can include, for example, a deflection detection device 110.2 connected to the control unit 109.2. The deflection detection device 110.2 detects deflection information DI, which is representative for a deflection of the optical element 107.2 in relation to the first supporting structure 111.1 in at least one degree of freedom from the first initial state. The control device 109 then derives the relative situation change information RSCI from the deflection information DI, for example on the basis of a change in the deflection information DI over time.

Thus, the relative situation control device 110 can include a number of relative situation control actuators 110.1 for actively adjusting the optical element 107.2, of which actuators only one relative situation control actuator 110.1 is respectively illustrated in FIGS. 2 and 3 for reasons of clarity. In some embodiments, a plurality of relative situation control actuators 110.1 are provided which act between the first supporting structure 111.1 and the optical element 107.1 in the manner of a parallel kinematic system. By way of example, provision can be made of six relative situation control actuators 110.1, which act in the manner of a hexapod kinematic system.

By way of example, a deflection detection device 110.2 can detect adjustment information VI, which is representative for an adjustment of the respective relative situation control actuator 110.1 from the calibrated first initial state. The control device 109.1 can then derive the relative situation change information RSCI from the adjustment information VI, for example on the basis of a change in the adjustment information VI over time.

Furthermore, the deflection detection device 110.2 can include at least one adjustment sensor 110.3, which is assigned to the respective relative situation control actuator 110.1. The adjustment sensor 110.3 outputs adjustment sensor information VSI, which is representative for the positioning movement of the relative situation control actuator 110.1, for example a change in length of the relative situation control actuator 110.1. The control device 109 can then derive the adjustment information VI from the adjustment sensor information VSI. It is understood that, in general, any number of adjustment sensors 110.3 can be provided per relative situation control actuator 110.1 in order to determine the adjustment information VI. In the present example, at least two adjustment sensors 110.3 are assigned to the respective relative situation control actuator 110.1 since this allows a relatively reliable, error-tolerant determination of the adjustment information VI.

However, it is understood that the adjustment information VI can in general also be detected in any other suitable manner in certain embodiments (in addition or as an alternative to the use of the adjustment sensors 110.3). Thus, for example, provision can be made for the control signals for the respective one relative situation control actuator 110.2 to be detected and stored without gaps in a history starting from the first initial state and for the adjustment information VI to be determined from this history of the control signals.

In certain embodiments, the control device 109 can optionally also include an imaging error detection device (not illustrated in more detail here), which produces at least one imaging error information IEI, which is representative for an imaging error of the imaging device. The control device 109 then derives the relative situation change information RSCI from the imaging error information IEI, for example on the basis of a change in the imaging error information IEI over time. These embodiments can use a known relationship between the imaging error of the imaging device and the change in static relative situation between the first supporting structure 111.1 and the second supporting structure 111.2 caused by creep or settling effects. Thus, certain changes in relative situation can cause characteristic imaging errors, which consequently have a characteristic fingerprint, which was determined in advance from theory and/or by simulation. These characteristic imaging errors or fingerprints can then be used to deduce an actual change in the static relative situation in the control device 109 during operation.

A relatively clear relationship between the imaging error and such a change in the static relative situation arises, for example, in the case of embodiments in which the optical imaging device 101 also includes passive optical components which are involved with the imaging but are not actively adjusted by way of the relative situation control device 110, instead are connected in a substantially rigid fashion to the first supporting structure 111.1 during operation, as indicated in FIG. 1 by the contour 107.3, which represents a stop. Here, only the actively set optical elements of the element group 107.1 are repositioned by the relative situation control device 110 to follow the change in the static relative situation, while the passive components, such as the stop 107.3, remain in their relative situation thus yielding a change in the static relative situation between the components 107.1 and 107.3, which is accompanied by a characteristic imaging error.

In some embodiments, the control device 109 can additionally or alternatively include a relative situation detection device, as indicated in FIG. 2 by the contour 109.4. In this case, the relative situation detection device 109.4 generates at least one relative situation information item RSI which is representative for the relative situation between the first supporting structure 111.1 and the second supporting structure 111.2 in at least one degree of freedom, the information being output to the control unit 109.2. The control device 109 then derives the relative situation change information RSCI from the relative situation information RSI, for example on the basis of a change in the relative situation information RSI over time. In this way, it is possible to realize relatively simple and precise detection of the relative situation change information RSCI.

While the above-described embodiments each realize a closed loop control circuit, embodiments with an open loop controlled system can also be realized, as mentioned above. Thus, in certain embodiments, the control device 109 can also use a creep model CM of the supporting spring device 113 to determine the relative situation change information RSCI in certain embodiments, wherein the creep model CM of the supporting spring device 113 describes the creep behavior of the supporting spring device 113. From this creep behavior known with sufficient accuracy, the relative situation change information RSCI can possibly be determined without a further sensor system and can be used directly for the control. However, in further embodiments the creep model CM can also be used for checking the plausibility of the relative situation change information RSCI, which was determined in another way, such as has been described above or below.

It should be mentioned again at this point that the embodiments described above or below for determining the relative situation change information RSCI can generally be combined in any manner, for example in order to obtain consolidated (e.g., averaged) relative situation change information RSCI. In addition or as an alternative thereto, individual embodiments for determining the relative situation change information RSCI can naturally also be used to check the plausibility of the results of the other embodiments for determining the relative situation change information RSCI.

In general, changing the adjustment force AFT can furthermore be implemented at any suitable time or triggered by any temporal events (e.g., specifiable intervals) and/or non-temporal events (e.g., detected shock loads, reaching a certain number of imaging procedures, starting up or shutting down the imaging device 101, etc.).

In the present example, the control device 109 activates the creep compensation mode CCM if the relative situation change represented by the relative situation change information RSCI exceeds a specifiable limit value LIM (i.e., if the following applies: RSCI>LIM). As a result of this, it is naturally possible to react relatively efficiently and in needs-based fashion to the creep or settling effects.

Additionally or alternatively, the control device 109 can activate the creep compensation mode CCM, as mentioned, on the basis of specifiable events, for example at specifiable time intervals, wherein the creep compensation mode is activated, for example, 1 μs to 10 years (e.g., 1 ms to 3 years, 10 minutes to 1 year) following the first operation of the imaging device 101 and/or a preceding activation of the creep compensation mode CCM.

In general, the control device 109 can be designed in any suitable manner in order to realize a control of the relative situation control device 110 that is adapted to the respective optical imaging process of the imaging device 101. It is possible to provide any suitable control bandwidths for controlling the relative situation control device 110. In some embodiments, the control device 109 has a control bandwidth of 0.5 μHz to 500 Hz (e.g., 0.01 Hz to 100 Hz, 0.1 Hz to 10 Hz.)

The degree of freedom or the degrees of freedom (DOF) in which, as a result of creep or settling effects, there is a change in the static relative situation relevant to the imaging process or the imaging error thereof can be any degree of freedom, up to all six degrees of freedom in space. In this case, any suitable limit values can be specified, which, if exceeded, involve or prompt a replacement of the previous target state S1 by the corrected target state S2.

In certain embodiments, the at least one degree of freedom DOF of the change in the static relative situation is a rotational degree of freedom, for example a rotational degree of freedom about a tilt axis extending transversely to the direction of gravity. The specifiable limit value then can be representative for a deviation of the relative situation between the first supporting structure 111.1 and the second supporting structure 111.2 from a specifiable relative target situation by 0.1 μrad to 1000 μrad (e.g., 1 μrad to 200 μrad, 10 μrad to 100 μrad). In addition or as an alternative thereto, the at least one degree of freedom DOF of the change in the static relative situation can be a translational degree of freedom, for example a translational degree of freedom along the direction of gravity. The specifiable limit value then can be representative for a deviation of the relative situation between the first supporting structure 111.1 and the second supporting structure 111.2 from a specifiable relative target situation by 0.1 μm 1000 μm (e.g., 1 μm to 200 μm, 10 μm to 100 μm).

In general, the adjustment device 115.1 can be designed in any suitable way for generating the adjustment force AFT. Optionally, the stiffness of the adjustment device 115.1 is naturally matched to the stiffness of the supporting spring devices 113.1 in order to obtain the desired decoupling effect of the vibration decoupling device 113 in the desired decoupling degrees of freedom. Optionally, the adjustment device 115.1 is designed in such a way that it supplies the smallest possible contribution to the stiffness of the support of the sensor frame 111.2 in these decoupling degrees of freedom, in which the vibration decoupling device 113 should provide decoupling. Optionally, the adjustment device 115.1 supplies substantially no contribution to the stiffness of the support of the sensor frame 111.2 in these decoupling degrees of freedom.

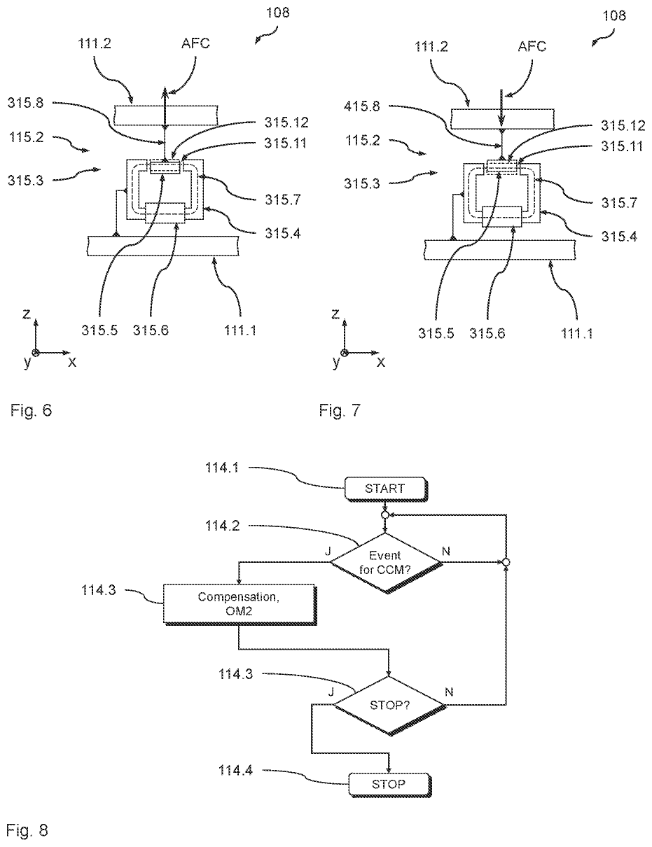

In general, the interplay between the supporting spring devices 113.1 and the adjustment device 115.1 can be configured in any suitable manner in order to obtain the desired vibration-decoupled support of the sensor frame 111.2. Thus, the adjustment device 115.1 can be configured in such a way that the adjustment force AFT at least partly relieves the supporting spring devices 113.1 and the adjustment force AFT is increased for at least partial compensation of the change in the static relative situation, as will yet be described below in conjunction with FIGS. 4 and 6. Likewise, the adjustment device 115.1 can however also be configured in such a way that the adjustment force AFT pre-stresses the supporting spring devices 113.1 and the adjustment force AFT is reduced for at least partial compensation of the change in the static relative situation, as will yet be described below in conjunction with FIGS. 5 and 7.

In the embodiments of FIGS. 4 and 6, the adjustment device 115.1 for relieving the supporting spring devices 113.1 is configured in such a way that the adjustment force

AFT compensates at least a portion of the total weight of the sensor frame 111.2 and the components carried thereby (such as the measuring device 109.1). It can be desirable for this fraction to be at least 0.1% to 30% (e.g., at least 0.5% to 6%, at least 1% to 3%) of the total weight. It can be desirable, for example, if at least a majority of the weight is absorbed by the adjustment force AFT, the supporting spring devices 113.1 hence being significantly relieved from the static loads and there also being reduced creep or settling effects on account of this relief.

The at least one active actuator unit 115.2 of the adjustment device 115.1, in general, can be functionally assigned, for example spatially assigned, to the supporting spring devices 113.1 in any suitable manner. Naturally, this can be implemented in coordination with an expected creep or settling behavior of the supporting spring devices 113.1. It can be desirable for, like in the present example, an active actuator unit 115.2 to be spatially assigned, and hence also functionally assigned, to each of the supporting spring devices 113.1. In this way, a relatively simple coordination with simple needs-based compensation of creep or settling effects is possible.

In general, any suitable actuator units 115.2 can be used to produce the adjustment force AFT. Thus, the adjustment device may include at least one active actuator unit 115.2 with a Lorentz actuator. These are desirable, for example, in that they have a stiffness which is at least substantially equal to zero over a certain actuation range along their adjustment force direction.

However, in the examples described below in conjunction with FIGS. 4 to 7, the adjustment device 115.1 includes in each case a number of active actuator units 115.2 with a reluctance actuator 115.3, 215.3, 315.3, 415.3. Compared to Lorentz actuators, these reluctance actuators 115.3 to 415.3 are desirable, for example, in that they can produce a comparatively high adjustment force while using comparatively small installation space and developing comparatively little heat. Moreover, the reluctance actuators 115.3 and 215.3 have a negative stiffness when the air gap is increased while the reluctance actuators 315.3 and 415.3 have a stiffness that at least substantially equals zero in the case of deflection over a certain actuation range from their rest situation (i.e., the situation with minimized reluctance). Using an appropriate coordination with the supporting spring devices 113.1, both of these effects can be desirable.

As initially described below with reference to the embodiment of FIG. 4, the active actuator unit 115.2 includes at least one reluctance actuator 115.3 with a first magnetic circuit component 115.4 and a second magnetic circuit component 115.5, which are assigned to one another for contactless interaction. Here, the first magnetic circuit component 115.4 is mechanically connected to the load-bearing first supporting structure 111.1 while the second magnetic circuit component 115.5 is mechanically connected to the sensor frame 111.2. Here, the first magnetic circuit component 115.4 includes a coil unit 115.6, which is connectable to a voltage source (not illustrated) of the control device 109 for the purposes of generating a magnetic field, indicated by the dashed contour 115.7, in the reluctance actuator 115.3. In this way, it is relatively easily possible to adapt the magnetic flux in this magnetic circuit, and hence the adjustment force contribution AFC or, in sum, the adjustment force AFT, by way of an appropriate control of the coil unit 115.6.

The reluctance actuator 115.3 in the embodiment of FIG. 4 is configured in the manner of a lifting magnet, where the contribution to the adjustment force results from the fact that the magnetic circuit of the reluctance actuator 115.3 attempts to reduce the air gap 115.11 of the magnetic circuit between the first magnetic circuit component 115.4 and the second magnetic circuit component 115.5.

Such a lifting magnet typically has a force profile where, in the case of an increase of the air gap, the force contribution AFC of the actuator unit 115.1 to the adjustment force AFT proportionally decreases, at least in sections, with an increasing change in the static relative situation. The contribution AFC of the actuator unit 115.1 to the adjustment force AFT decreases over-proportionately, at least in sections, with an increasing change in the static relative situation. Consequently, the actuator unit 115.1 has a negative stiffness, as a result of which the stiffness of the supporting spring devices 113.1 can be at least partly compensated. Consequently, the negative stiffness of the actuator unit 115.1 can be used in combination with corresponding coordination with the supporting spring devices 113.1 in order, in total, to obtain comparatively low stiffness in the decoupling degrees of freedom.

As a result of this, it is possible, for example, to use supporting spring devices 113.1 with a comparatively high stiffness, which are therefore subject to creep and settling effects to a lesser extent. The high stiffness of the supporting spring devices 113.1 can then be compensated for by the negative stiffness of the actuator units 115.1, such that, in total, at least a nevertheless comparatively low stiffness is obtained in the decoupling degrees of freedom.

In general, the actuator unit 115.2 may be designed in such a way that it itself already provides the desired decoupling in certain decoupling degrees of freedom involved (for the support of the second supporting structure 111.2). In the present example, the actuator unit 115.2 is mechanically connected to the second supporting structure 111.2 via a decoupling device 115.8. Here, the decoupling device 115.8 is configured to generate at least partial mechanical decoupling between the actuator unit 115.2 and the supporting structure 111.2 in a plurality of decoupling degrees of freedom that differ from the adjustment force direction of the force AFC. In the present example, a decoupling degree of freedom is a translational degree of freedom extending transversely to the adjustment force direction. Additionally, there is decoupling in a rotational degree of freedom about an axis which extends transversely to the adjustment force direction. A vibration decoupling can be obtained in a simple manner in all these cases.

To this end, the decoupling device 115.8 is configured as the flexible decoupling element that is elongated in the adjustment force direction, specifically as a leaf spring element that is elongated in the adjustment force direction or as a narrow, for example flexible, rod spring element that is elongated in the adjustment force direction. The desired decoupling can be easily obtained in both cases.

In the embodiment of FIG. 4, the adjustment device 115.1 is configured in such a way that the adjustment force AFT at least partly relieves the supporting spring devices 113.1 and the adjustment force AFT is increased for at least partial compensation of the change in the static relative situation, as already described above.

In the embodiment of FIG. 5 described below, the adjustment device 115.1 is however configured in such a way that the adjustment force AFT pre-stresses the supporting spring devices 113.1 and the adjustment force AFT is decreased for at least partial compensation of the change in the static relative situation. In this case, in terms of basic design and functionality, the embodiment of FIG. 5 corresponds to the embodiment of FIG. 4, and so only differences shall be discussed here. Similar components have been provided with reference signs whose values have been increased by 100 and, provided nothing else is explicitly stated, express reference is made to the explanations given in relation to the embodiment of FIG. 4 with respect to the properties of these components.

The difference between the embodiment of FIG. 5 and the embodiment of FIG. 4 consists in the fact that the reluctance actuator 215.3 is reversed (in comparison with the actuator 115.3) such that the adjustment force AFT pre-stresses the supporting spring devices 113.1 and the adjustment force AFT is reduced for at least partial compensation of the change in the static relative situation. To this end, apart from that, it is only the decoupling device 115.8 that was adapted accordingly.

A further embodiment is described below on the basis of FIG. 6. In this embodiment, a first magnetic core unit 315.9 of the first magnetic circuit component 315.4 (connected to the first supporting structure 111.1) and a second magnetic core unit 315.10 of the second magnetic circuit component 315.5 (connected to the second supporting structure 111.2) form a magnetic core of a magnetic circuit of the reluctance actuator 315.3, wherein two air gaps 315.11 are formed.

In this case too, the actuator unit 315.2 can be designed, in general, in such a way that it itself already provides the desired decoupling in the decoupling degrees of freedom involved (for the support of the second supporting structure 111.2). In the present example, the actuator unit 315.2 is mechanically connected to the second supporting structure 111.2 via a decoupling device 315.8. Here, the decoupling device 315.8 is designed like the decoupling device 115.8, and so in this respect reference is made to the explanations given above in relation to the latter.

Here, the reluctance actuator 315.3 has a reference state in which the magnetic circuit has a minimized magnetic resistance (i.e., a minimized reluctance), as indicated by the dashed contour 315.12.

Furthermore, the reluctance actuator 315.3 has an actuating state, in which the reluctance actuator 315.3 provides a contribution AFC to the adjustment force AFT. Here, the magnetic field 315.7 is generated in the first magnetic core unit 315.4 and in the second magnetic core unit 315.5, the magnetic field lines of the magnetic field respectively passing through the air gaps in a magnetic field line direction in the reference state. Furthermore, in the actuating state, the first magnetic core unit 315.4 and the second magnetic core unit 315.5 are deflected transversely to the magnetic field line direction of the magnetic field 315.7 with respect to one another as compared to the reference state 315.12.

In the embodiment of FIG. 7, the deflection of the second magnetic core unit 315.5 with respect to the first magnetic core unit 315.4 is chosen in such a way that the contribution AFC to the adjustment force AFT once again at least partly relieves the supporting spring devices 113.1 and the resultant adjustment force AFT is increased for at least partial compensation of the change in the static relative situation, as already described above.

The embodiment of FIG. 6 is desirable in that the contribution AFC of the actuator unit 315.3 to the adjustment force AFT is substantially constant, at least in sections, with increasing change in the static relative situation and consequently the actuator unit 315.3 has the above-described stiffness near or equal to zero in this range of the deflection. In this way, the influence of the actuator unit 315.3 on the stiffness profile of the supporting spring devices 113.1 can be kept low or constant.

In the embodiment of FIG. 7 described below, the adjustment device 115.1 is ultimately once again configured in such a way that the adjustment force AFT pre-stresses the supporting spring devices 113.1 and the adjustment force AFT is decreased for at least partial compensation of the change in the static relative situation. In terms of basic design and functionality, the embodiment of FIG. 7 corresponds to the embodiment of FIG. 6, and so only the differences shall be discussed here. Similar components have been provided with reference signs whose values have been increased by 100 and, provided nothing else is explicitly stated, express reference is made to the explanations given above in relation to the embodiment of FIG. 6 with respect to the properties of these components.

The difference between the embodiment of FIG. 7 and the embodiment of FIG. 6 merely consists in the fact that, in the embodiment of FIG. 7, the deflection of the second magnetic core unit 315.5 with respect to the first magnetic core unit 315.4 is chosen in such a way that the contribution AFC to the adjustment force AFT pre-stresses the supporting spring devices 113.1 and the adjustment force AFT is reduced for at least partial compensation of the change in the static relative situation. To this end, apart from that, it was only the decoupling device 415.8 that was adapted accordingly.

Here, for example, the second magnetic core unit 315.5 may pass through the reference state 315.12 during the change in the static relative situation. In this case, the force AFC in the reference state 315.12 becomes equal to zero and then reverses in case of a further change in the static relative situation, with a state as in FIG. 6 being attained then, which then counteracts the change in the static relative situation.

Furthermore, it is understood that, in general, the various actuator units 115.3 to 415.3 (of FIGS. 4 to 7) can also be combined with one another as desired within the adjustment device. For example, the respective actuator unit 115.3 to 415.3 can be specifically matched to the associated supporting spring device 113.1 and the creep behavior thereof or to the load situation thereof on account of the mass distribution of the supported second supporting structure 111.2.

Using the designs described above, it is possible to perform the method according to the disclosure as described above. Here, as shown in FIG. 8, the procedure is initially started in a step 114.1. This is carried out, for example, with the first-time start-up of the imaging device 101, with the imaging device then being in the first operating state OM1.

Then, in a step 114.2, a check is carried out within the control device 109 as to whether one of the above-described events, which triggers the activation of the creep compensation mode CCM, has occurred. This check is repeated if this is not the case. However, if this is the case, the adjustment force AFT is altered or adapted in the above-described manner in the control device 109 in a step 114.3, wherein the control device 109 then puts the imaging device 101 into the second operating state OM2 (which then replaces the first operating state OM1). Then, in a step 114.3, a check is carried out in the control device 109 as to whether the procedure should be terminated. If not, there is a jump back to the step 114.2. Otherwise, the procedure is terminated in a step 114.4. Otherwise, reference is made to the explanations above with respect to further details of the method so as to avoid repetition.

In the foregoing, the present disclosure was only described on the basis of examples in which the relative situation of each optical element of the element group 107.1 was actively adjusted in relation to the central reference 112. However, it is understood that in some embodiments only some of the optical elements (possibly even only one optical element) of the element group 107.1 may be actively adjusted directly in relation to the central reference 112 while the remaining optical elements of the element group 107.1 are actively adjusted relative to one of these optical elements that has been actively set with respect to the central reference 112. For example, only one of the optical elements of the element group 107.1 can serve as a reference element and can be directly actively set with respect to the central reference 112, while all other optical elements of the element group 107.1 are actively set relative to this reference element (and hence only indirectly with respect to the central reference 112).

The present disclosure was described above exclusively on the basis of examples from the area of microlithography. However, it is understood that the disclosure can also be used in the context of any other optical applications, for example imaging methods at different wavelengths, in which similar problems arise with respect to the support of heavy optical units.

Furthermore, the disclosure can be used in connection with the inspection of objects, such as for example the so-called mask inspection, in which the masks used for microlithography are inspected for their integrity, etc. In FIG. 1, a sensor unit, for example, which detects the imaging of the projection pattern of the mask 104.1 (for further processing), then takes the place of the substrate 105.1. This mask inspection can then take place both substantially at the same wavelength as is used in the later microlithographic process. However, it is likewise possible also to use any desired wavelengths deviating therefrom for the inspection.

The present disclosure has been described above on the basis of specific exemplary embodiments showing specific combinations of the features. It should expressly be pointed out at this juncture that the subject matter of the present disclosure is not restricted to these combinations of features, rather all other combinations of features such as are evident from the following patent claims also belong to the subject matter of the present disclosure.

What is claimed is:

1. An arrangement, comprising:
an optical element;
a first supporting structure configured to support the optical element;
a second supporting structure;
a vibration decoupling device comprising a plurality of supporting spring devices supporting the second structure;
a measuring device configured to measure a position and/or an orientation of the optical element in relation to a reference in from one to six degrees of freedom in space; and
a creep compensation device configured to compensate a change in a static relative situation between the first and second supporting structures in at least one correction degree of freedom,
wherein:
the first supporting structure supports the second supporting structure via the plurality of supporting spring devices;
the supporting spring devices act kinematically parallel to one another between the first and second supporting structures;
for each of supporting spring device, the supporting spring device defines a supporting force direction along which the supporting spring device exerts a supporting force between the first and second supporting structures;
for each supporting spring device, the supporting spring device defines a supporting length along the supporting force direction defined by the supporting spring device;
the second supporting structure supports the measuring device;
the creep compensation device comprises an adjustment device;
the adjustment device comprises an actuator unit configured to act kinematically parallel to the supporting spring devices between the first and second supporting structures;
the adjustment device is configured to: i) exert an adjustment force on the second supporting structure; and ii) alter the adjustment force to at least partially compensate the change in the static relative situation; and
the arrangement is an arrangement of a microlithographic optical imaging device.

2. The arrangement of claim 1, wherein the change in the static relative situation is due to a creep process at the supporting spring devices.

3. The arrangement of claim 1, wherein at least one of the following holds:
the actuator unit comprises a reluctance actuator; and
the actuator unit comprises a Lorentz actuator.

4. The arrangement of claim 1, wherein one of the following holds:
the adjustment device is configured so that the adjustment force at least partially relieves the supporting spring devices, and the adjustment force is increased to at least partially compensate the change in the static relative situation; and
the adjustment device is configured so that the adjustment force pre-stresses the supporting spring devices, and the adjustment force is decreased to at least partially compensate the change in the static relative situation.

5. The arrangement of claim 4, wherein the adjustment device is configured to relieve the supporting spring devices so that the adjustment force compensates at least 0.1% to 30% of the total weight of the second supporting structure and the components carried by the second supporting structure.

6. The arrangement of claim 1, wherein the actuator unit is spatially assigned to a supporting spring device.

7. The arrangement of claim 1, wherein the actuator unit comprises a reluctance actuator, and the reluctance actuator comprises first and second magnetic circuit components assigned to one another to contactlessly interact.

8. The arrangement of claim 7, wherein:
the first magnetic circuit component comprises a first magnetic core;
the second magnetic circuit component comprises a second magnetic core;
the reluctance actuator comprises a magnetic circuit;
the magnetic circuit comprises a magnetic core;
the magnetic core comprises the first and second magnetic circuits and two air gaps;
the reluctance actuator has a reference state in which the magnetic circuit has a minimized magnetic resistance;
the reluctance actuator has an actuating state in which the reluctance actuator is configured to provide a contribution to the adjustment force;
in the reference state, the reluctance actuator is configured to generate a magnetic field in the first magnetic core unit and in the second magnetic core unit;
the magnetic field has magnetic field lines of the magnetic field respectively passing through the two air gaps; and
in the actuating state, the reluctance actuator is configured so that, compared to the reference state, the first magnetic core unit and the second magnetic core unit are deflected with respect to each other transversely to the magnetic field line direction.

9. The arrangement of claim 1, wherein at least one of the following holds:
the actuator unit has a negative stiffness;
the actuator unit is configured so that a contribution of the actuator unit to the adjustment force proportionally decreases, at least in sections, with increasing change in the static relative situation;
the actuator unit is configured so that a contribution of the actuator unit to the adjustment force over-proportionately decreases, at least in sections, with increasing change in the static relative situation; and
the actuator unit is configured so that a contribution of the actuator unit to the adjustment force is substantially constant, at least in sections, with increasing change in the static relative situation.

10. The arrangement of claim 1, further comprising a second decoupling device,
wherein:
the actuator unit is configured to exert a contribution to the adjustment force on the second supporting structure in an adjustment force direction;
the second decoupling device mechanically connects the actuator unit to a member selected from the group consisting of the first supporting structure and the second supporting structure;
the second decoupling device is configured to at least partially mechanically decouple the actuator unit and the member in a degree of freedom that differs from the adjustment force direction.

11. The arrangement of claim 1, further comprising a second decoupling device extending in a direction of the adjustment force,
wherein:
the actuator unit is configured to exert a contribution to the adjustment force on a member selected from the group consisting of the first supporting structure and the second supporting structure; and
the second decoupling device mechanically connects the actuator unit to the member.

12. The arrangement of claim 1, further comprising a control device configured to control the adjustment device to change the adjustment force based on a change in length of a supporting spring device along the supporting force direction of the supporting spring device.

13. The arrangement of claim 1, further comprising:
a detection device configured to detect a relative situation detection value representative of the relative situation; and
a control device configured to control the adjustment device to change the adjustment force based on the relative situation detection value.

14. The arrangement of claim 13, wherein the control device is configured to control the adjustment device only when a deviation of the relative situation detection value from a target value exceeds a specifiable limit value.

15. The arrangement of claim 13, wherein at least one of the following holds:
the at least one correction degree of freedom is a rotational degree of freedom about a tilt axis extending transversely to the direction of gravity; and
the at least one correction degree of freedom is a translational degree of freedom along the direction of gravity.

16. An optical imaging device, comprising:
an illumination device comprising a first optical element group; and
a projection device comprising a second optical element group,
wherein:
the illumination device is configured to illuminate an object;
the projection device is configured to project an image of the object onto a substrate; and
at least one member selected from the group consisting of the illumination device and the projection device comprises an arrangement according to claim 1.

17. A method of using a microlithographic optical imaging device comprising an illumination device and a projection device, the illumination device comprising a first optical element group, and the projection device comprising a second optical element group, the method comprising:
using the illumination device to illuminate an object; and
using the projection device to project an image of the object onto a substrate,
wherein at least one member selected from the group consisting of the illumination device and the projection device comprises an arrangement according to claim 1.

18. A method of operating a microlithographic optical imaging device comprising a first supporting structure supporting a second supporting structure via a plurality of supporting spring devices of a vibration decoupling device, the supporting spring devices acting kinematically parallel to one another between the first and second supporting structures, each supporting spring device defining a supporting force along which the supporting spring device exerts a supporting force between the first and second supporting structures, each supporting spring device defining a supporting length along the supporting force direction defined by the supporting spring device, the first supporting structure supporting an optical element of the imaging device, the second supporting structure supporting a measuring device configured to measure a position and/or an orientation of the optical element in relation to a reference in from one to six degrees of freedom in space, the method comprising:
exerting an adjustment force on the second supporting structure in a manner kinematically parallel to the supporting spring devices between the first and second supporting structures; and
altering the adjustment force to at least partially compensate in at least one degree of freedom, a change in the static relative situation between the first and second supporting structures,
wherein the change in the static relative situation being is caused by a creep process at the supporting spring devices.

19. The method of claim 18, wherein at least one of the following holds:
the actuator unit comprises a reluctance actuator that generates the adjustment force; and
the actuator unit comprises a Lorentz actuator that generates the adjustment force.

20. The method of claim 18, wherein one of the following holds:
the adjustment force at least partly relieves the supporting spring devices, and the adjustment force increases to at least partially compensate the change in the static relative situation; and
the adjustment force pre-stresses the supporting spring devices, and the adjustment force decreases to at least partially compensate the change in the static relative situation.
